(19) United States
(12) Patent Application Publication
(10) Pub. No.: US 2013/0335383 A1
(43) Pub. Date: Dec. 19, 2013

(54) REMOVAL OF MOLYBDENUM

(71) Applicant: Teruo Sasagawa, San Jose, CA (US)

(72) Inventor: Teruo Sasagawa, San Jose, CA (US)

(73) Assignee: QUALCOMM MEMS Technologies, Inc., San Diego, CA (US)

(21) Appl. No.: 13/527,467

(22) Filed: Jun. 19, 2012

(51) Int. Cl. C23F 1/02; G06F 3/038; G06T 1/00; G02B 26/00; H05K 13/00

(52) U.S. Cl. 345/204; 359/290; 216/13; 345/418

(57) ABSTRACT

This disclosure provides systems, methods and apparatus which involve selectively removing a sacrificial portion of molybdenum (Mo) relative to other structural materials in a self-limiting manner. The Mo is only partially removed, leaving behind a remaining portion of molybdenum. The self-limiting etch can form an internal cavity by removing only a portion of a Mo layer between electromechanical systems electrodes. The remaining Mo can serve as a support structure between the electrodes.

### TECHNICAL FIELD

This disclosure relates generally to methods of etching molybdenum, release in electronic devices and more particularly to removal of molybdenum from hard to access locations, such as sacrificial molybdenum between electrodes of electromechanical systems.

### DESCRIPTION OF THE RELATED TECHNOLOGY

Electromechanical systems (EMS) include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a fixed or stationary layer deposited on a substrate and the other plate may include a reflective membrane separated from the fixed or stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Molybdenum (Mo) sacrificial layers can be removed by exposure to fluorine based etchants, such as Xenon Difluoride (XeF₂). XeF₂ etching is conducted for an amount of time calculated to ensure full removal of the sacrificial Mo material. Because the etch proceeds at least partially sideways to reach between electrodes, at least some of the structural material meant to remain in the electromechanical systems device after removal of the sacrificial layer continues to be exposed to the etch while the remainder of the sacrificial material continues to be removed. As a result of this prolonged exposure, over-etching can occur and damage the structural materials. While it has advantages over other fluorine-based etchants, XeF₂ is also an expensive and rare material.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of selectively etching molybdenum. The implementation includes providing a partially fabricated electronic device on a substrate in a reaction chamber. The partially fabricated electronic device includes molybdenum and at least one structural material. The implementation also includes providing a chlorine source and an oxygen source through a remote plasma generator to form activated species of chlorine and oxygen. The implementation includes selectively etching the molybdenum relative to the at least one structural material by delivering the activated species of chlorine and oxygen from the remote plasma generator to the partially fabricated electronic device in the reaction chamber, where the selectively etching is self-limiting. In some implementations, the self-limiting selective etch can only partially remove the molybdenum from within the at least one structural material of the partially fabricated electronic device, the molybdenum being embedded in the at least one structural material. In some implementations, the at least one structural material can include aluminum oxide (Al₂O₃), silicon dioxide (SiO₂), silicon oxynitride (SiON), nickel (Ni), iron (Fe), platinum (Pt) and gold (Au).

Another innovative aspect described in this disclosure can be implemented in an electromechanical systems device. The electromechanical systems device includes a substrate having a first electrode layer formed thereon and a movable second electrode layer formed over the first electrode layer and spaced apart from the first electrode layer by a collapsible cavity. The electromechanical systems device includes at least one support structure supporting the movable second electrode layer over the first electrode layer. The at least one support structure can include molybdenum and the structural materials surrounding the collapsible cavity include at least one of silicon and silicon nitride. In some implementations, the structural materials can also include one or more of aluminum oxide (Al₂O₃), silicon dioxide (SiO₂), silicon oxynitride (SiON), nickel (Ni), iron (Fe), platinum (Pt) and gold (Au). The at least one support structure can have a re-entrant profile. The length of the cavity parallel to the substrate can be at least 50 times of a height of the cavity perpendicular to the substrate. The electromechanical systems device can be an interferometric modulator device. The electromechanical systems device can be part of a display apparatus. The display apparatus can include a display, a processor configured to communicate with the display and to process image data, and a memory device that is configured to communicate with the processor.

Another innovative aspect described in this disclosure can be implemented in an electromechanical systems device. The electromechanical systems device includes a substrate having a first electrode layer formed thereon, a movable second electrode layer formed over the first electrode layer and spaced apart from the first electrode layer by a cavity, and a means for supporting the second electrode layer over the cavity including molybdenum. The electromechanical systems device includes at least one of silicon or silicon nitride exposed to the cavity. The means for supporting can be a support post. The support post can have a re-entrant profile.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows a schematic example of an etch system employing a remote plasma generator.

FIG. 10 shows an example of a flow diagram illustrating a method of self-limitingly etching molybdenum from a partially fabricated electronic device.

FIGS. 11A-12 show examples of cross sectional views illustrating aspects of a process flow for self-limiting etching of molybdenum.

FIGS. 13A-13D show examples of cross sectional views during various stages of self-limiting etching of sacrificial material during the fabrication of an electromechanical systems device.

FIGS. 14A and 14B illustrate the results of self-limited removal of sacrificial material with different etch hole locations.

FIGS. 15A-15D show example top view photomicrographs depicting progressive molybdenum etching by chlorine/oxygen active species etchant introduced through etch holes.

FIGS. 16A-16D show example cross sectional photomicrographs of the examples of FIGS. 15A-15D.

FIGS. 17A-17D show example top view photomicrographs depicting progressive molybdenum etching by chlorine/oxygen active species etchant flowing through etch holes.

FIGS. 18A-18D show example cross sectional photomicrographs of the examples of FIGS. 17A-17D.

FIG. 19 shows an example graph of the etching rate dependence on gas flow ratio provided through a remote plasma generator.

FIGS. 20A and 20B show examples of system block diagrams illustrating a display device that includes a plurality of interferometric modulators.

FIG. 21 illustrates examples of paths of activated species in cavities.

FIG. 22 is a graph illustrating examples of the relative number of active species of a gas versus the distance from the entrance of a cavity for different activated species of gas.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

Some implementations disclosed herein include a method for etching molybdenum in the presence of a structural material with increased selectivity using a chlorine and oxygen downstream plasma process. Molybdenum can be removed from confined spaces such as sacrificial molybdenum in between electromechanical systems electrodes, in a self-limiting manner. For example, in some implementations, the etch is self-limiting because the etch front stops before all the sacrificial molybdenum is removed even if etchant continues to be supplied. In some implementations, the etch is self-limiting because the molybdenum is embedded in structural material such that a cavity is formed during the etching (for example, the cavity can be surrounded by structural material that is not etched). In one implementation, the etch is self-limiting because the cavity so formed has one or more dimensions or widths that is less than 10 times the mean free path and an aspect ratio of depth to width greater than 10.

Particular implementations of the subject matter described in this disclosure can be implemented to realize one or more of the following potential advantages. The etch processes disclosed herein provide high selectivity between molybdenum and other structural materials without the need for ion bombardment. High selectivity, in turn, can remove sacrificial material from between electrodes and leave the structural material free from residues, particles and damage. Additionally, exposed structural materials can be formed from silicon or silicon nitride, which is not possible with fluorine-based etchant. The self-limiting nature of the etch can be employed to leave molybdenum behind is a desired pattern, such as posts holding up a movable electrode in an electromechanical systems (EMS) device.

An example of a suitable EMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The absorber can be a partially reflective metallic or semiconductor layer. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

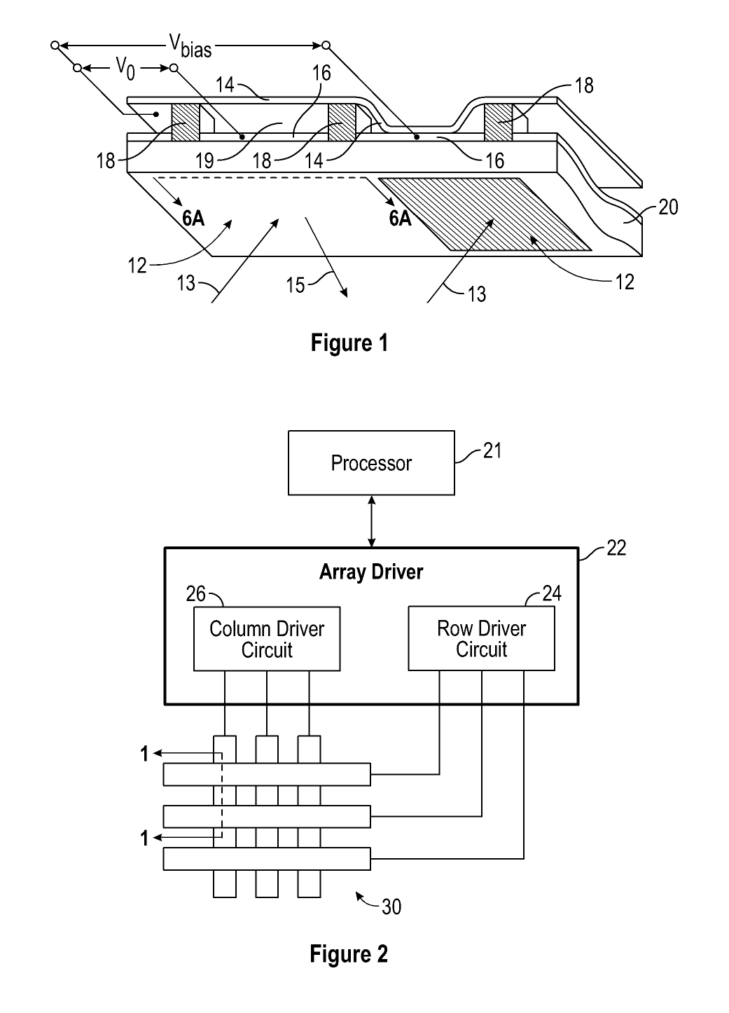

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The reflective layers include one or more reflective surfaces. The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

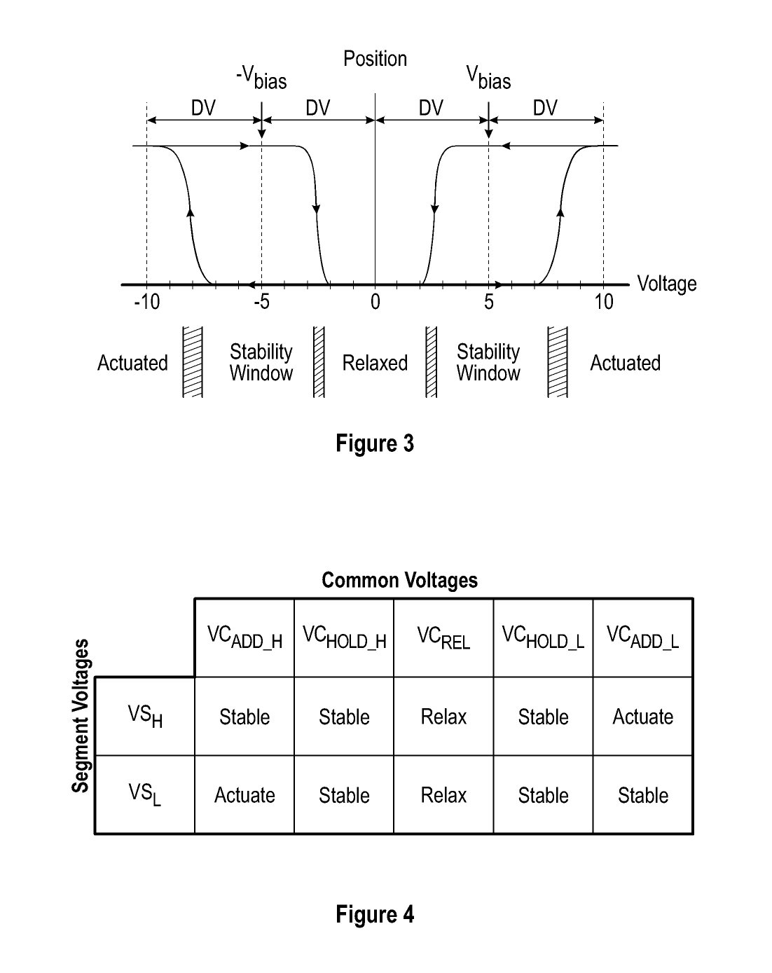

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

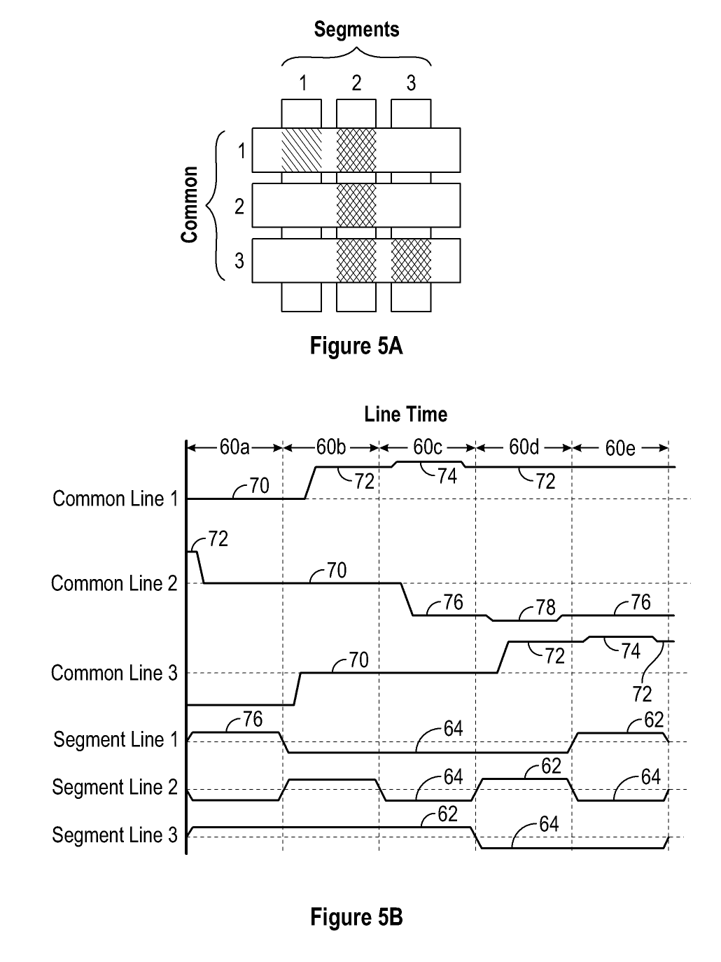

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

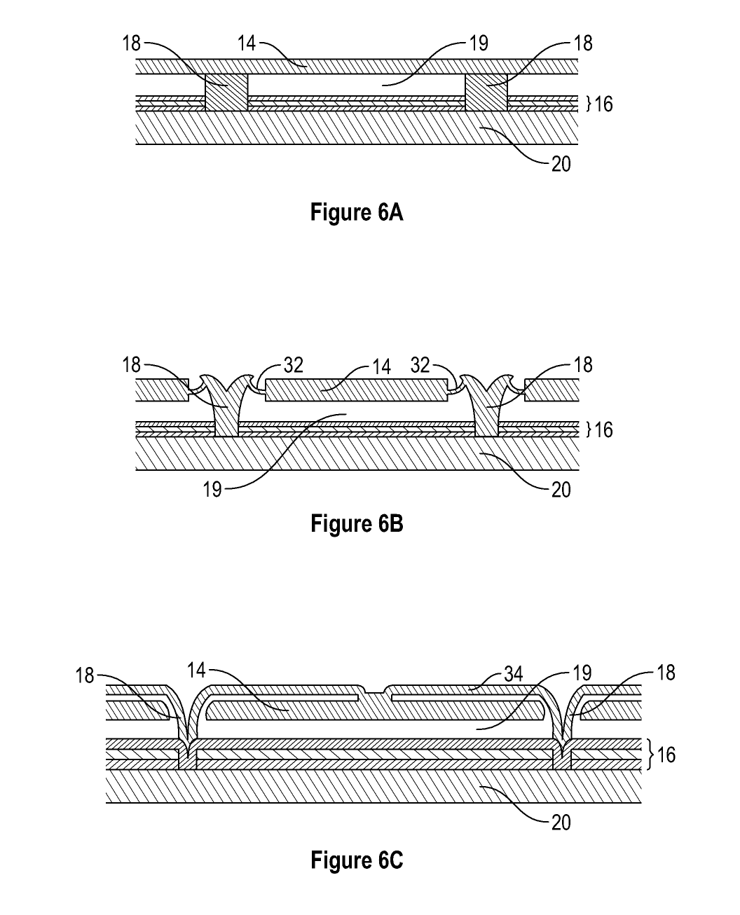

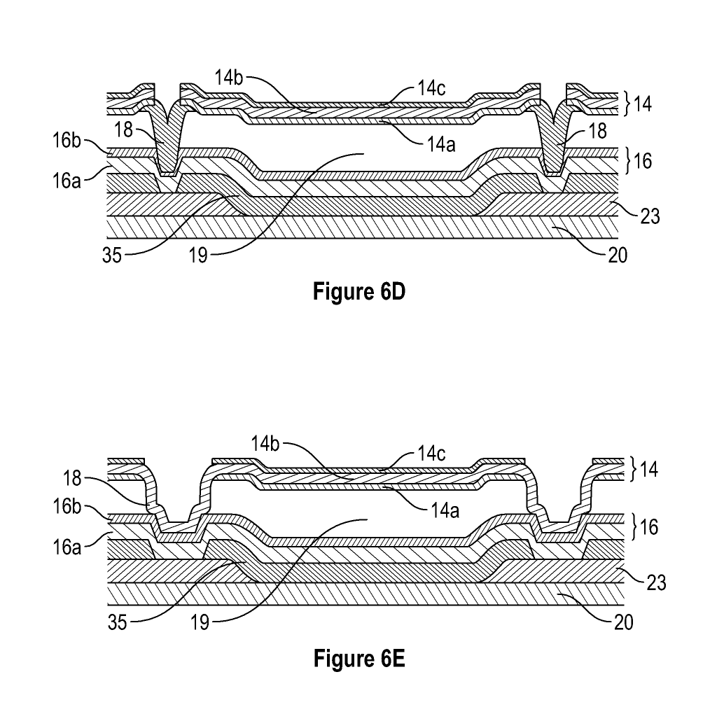

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports 18 at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as supports or support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another. In the implementation of FIG. 6C, the supports 18 are formed integrally with the deformable layer 34.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E includes support posts 18 that are integrally formed with the movable reflective layer 14, which contacts the underlying optical stack 16 at multiple locations. The curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

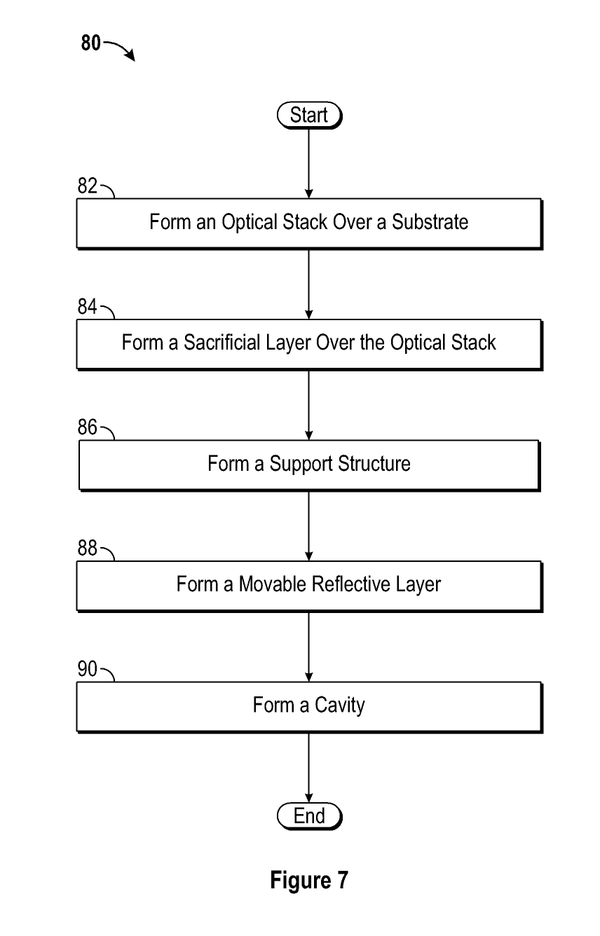

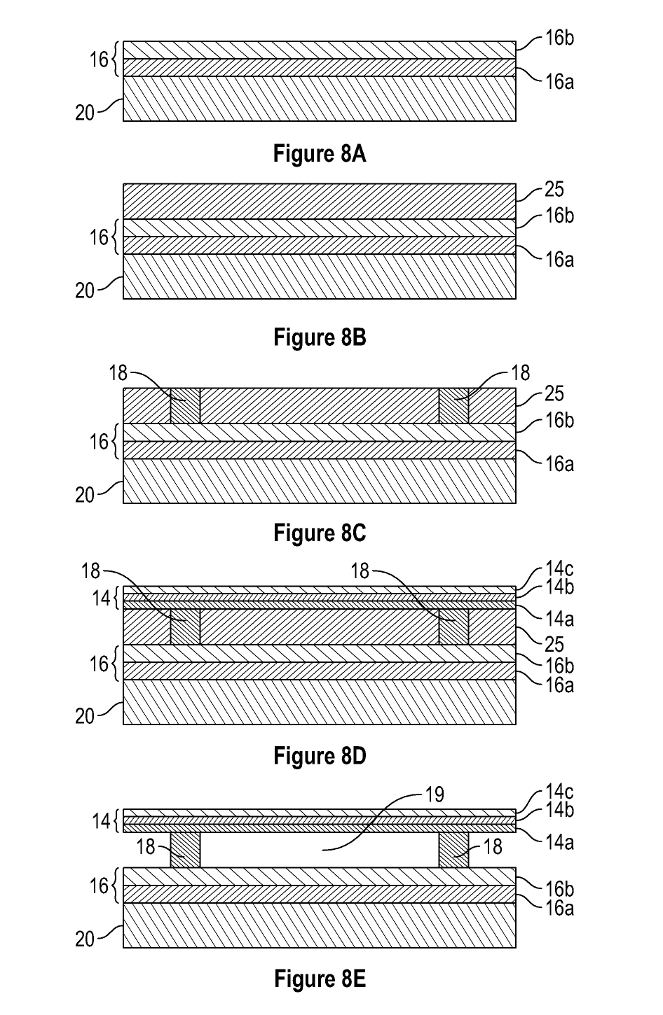

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. At least a portion of sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a selectively-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

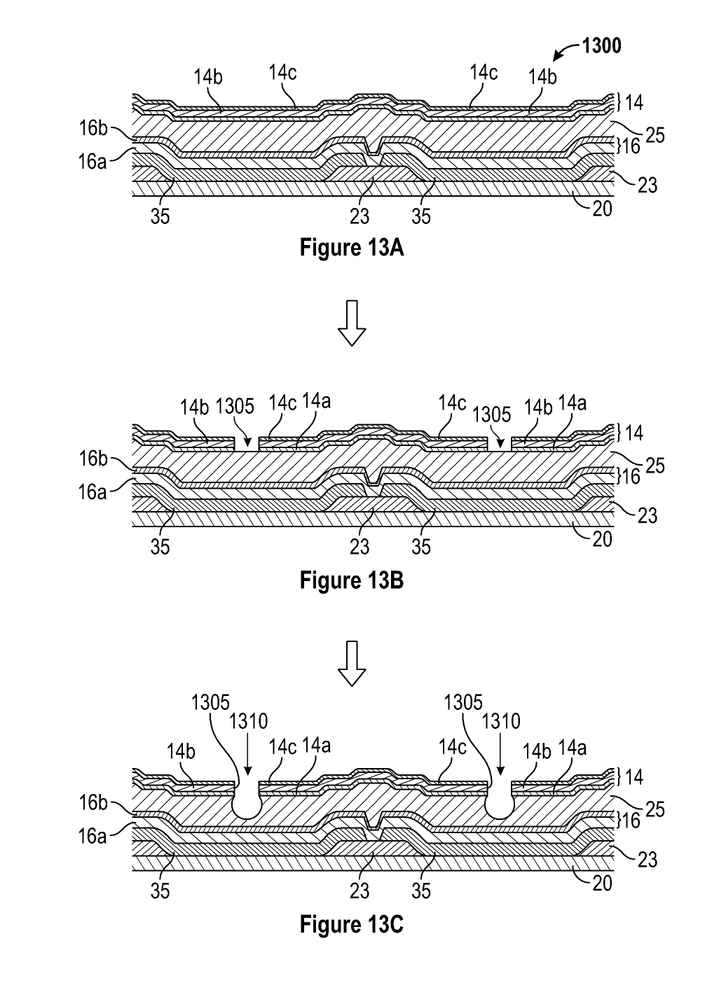

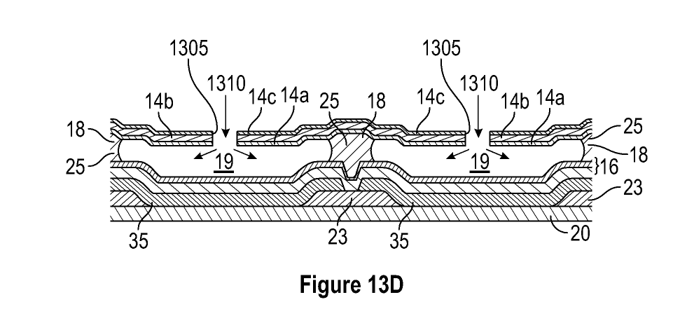

The fabrication process can be conducted in sequences other than that shown in FIG. 7, and some blocks can be combined with other blocks, while some blocks can include multiple processes. For example, in a self-supporting implementation (see FIGS. 6C and 6E), blocks 86 and 88 can be combined. In the implementation of FIGS. 13A-13B, blocks 84 and 86 can be combined.

Improving selectivity in etching processes becomes increasingly important as feature dimensions shrink. In particular, in the fabrication of EMS devices, sacrificial materials are often disposed under and/or between one or more non-sacrificial materials. Such non-sacrificial or permanent components can be referred to as structural materials or components, and they may have structural, electrical, and/or optical functions. Undesired etching of the structural components can result in changes in the physical and/or optical properties of the device, for example, changes in the color of a display element, such as an IMOD. In some implementations, excessive etching is particularly acute at or around openings in a device that provide etchant access to the sacrificial material. The confined and difficult to access volume between EMS electrodes results in extended contact between the structural materials with, for example, excess etchant, etching byproducts, and/or etching intermediates, each of which can play a role in continued etching of the target material and damage to structural materials. In a confined volume with reduced diffusion, the relative concentrations of the etchant, etching byproducts, and/or reactive etching intermediates change over the course of the etching process. As a consequence, the effective etching selectivity can also change during the etching process.

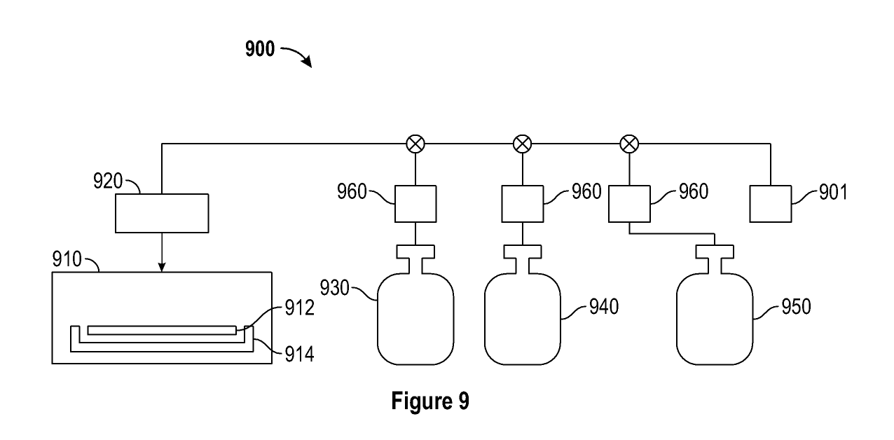

FIG. 9 shows a schematic example of an etch system employing a remote plasma generator. The remote plasma system 900 can include a remote plasma generator 920, one or more gas sources 930, 940 and 950, and an etch chamber 910. In some implementations, the one or more gas sources can include an oxygen source gas, a chlorine source gas, and a carrier gas. In some implementations, each of the one or more gas sources can be connected to a valve 960. The valve 960 can be, for example, a mass flow control (MFC) valve. In some implementations, the etch chamber 910 can include a support 914 configured to support a substrate 912 (e.g., a partially fabricated electronic device). The support 914 can be sized and shaped to accommodate substrates suitable for displays. Examples include standard rectangular glass substrate formats G2.5 (370 mm×920 mm) G45 (730 mm×920 mm) and G11 (3.3 m×3.1 m). In some implementations, the remote plasma system 900 can include a controller (not shown). The mode of operation of the remote plasma system 900 may change depending on the frequency of the power source, the operating pressure, and/or the processing temperature. The remote plasma can use, for example, inductive coupled plasma (ICP), transformer couple plasma (TCP) or microwave energy, similar to those commonly employed for downstream ashing systems.

The chlorine source can include, for example, diatomic chlorine (Cl₂), and hydrogen chloride (HCl), among others. The oxygen source can include, for example, water (H₂O), diatomic oxygen (O₂), ozone (O₃), and nitrous oxide (N₂O), among others. The carrier gas can include, for example, nitrogen, helium, neon, xenon, and/or argon.

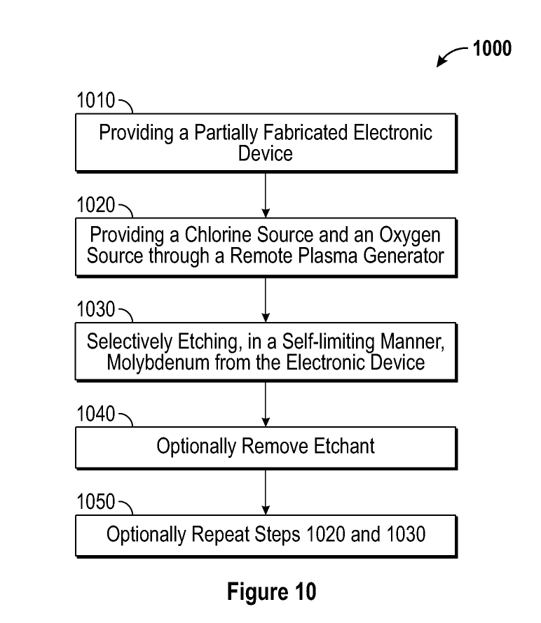

FIG. 10 shows an example of a flow diagram illustrating a method of a self-limitingly etching molybdenum from a partially fabricated device. The method exhibits selectivity between molybdenum and a structural material, for example, aluminum, thereby eliminating the need for an etch stop layer to protect the structural material. Additionally, the method can be self-limiting, thereby eliminating the need for a timed etch process. The method 1000 includes a block 1010 for providing a partially fabricated electronic device. The method 1000 also includes a block 1020 for providing a chlorine source and an oxygen source through a remote plasma generator. The activated species of the chlorine products and oxygen products from the remote plasma generator can be delivered to a downstream reaction or etch chamber. The method 1000 also includes a block 1030 for selectively etching the electronic device. For example, the activated species selectively etch molybdenum relative to at least one structural material. In some implementations, the selective etching using remotely activated chlorine and oxygen can be employed in a self-limiting fashion. In block 1040, the etchant is optionally removed, for example, by purging with a gas and/or by vacuum pumping. In block 1050, steps 1120 and 1130 are optionally repeated. For example, some implementations use an etching chamber with an insufficient volume to hold enough etchant to completely etch a device in a single cycle. Some implementations use different ratios of the chlorine source and the oxygen source in different cycles. In some implementations, purging between etching cycles removes reactive etching byproducts and/or intermediates, thereby improving selectivity. Implementations of the method are useful for the fabrication of EMS devices including a hole or cavities, for example, the methods can be used for the release etch of any of unreleased interferometric modulators (see, e.g., FIG. 8C) to form the corresponding released interferometric modulators similar to those illustrated in FIGS. 6A-6E, although the post configuration can be different in a self-limiting implementation.

At block 1010, a partially fabricated electronic device is provided. The partially fabricated electronic device may be placed on the support 914 of the chamber 910. In some implementations, the partially fabricated electronic device may be similar to those described in any of the implementations herein. For example, in some EMS implementations, the partially fabricated electronic device includes a molybdenum layer between EMS electrodes. In some IMOD implementations, the partially fabricated electronic device includes a substrate, an optical stack, a molybdenum layer, and a reflective layer in that sequence. In some IMOD implementations, the partially fabricated electronic device includes a black mask structure in inactive regions between pixel active regions, such as under support posts.

At block 1020, a chlorine source and an oxygen source are provided. In some implementations, the remote plasma system is adapted to provide to the chamber 910 a process gas containing chlorine and oxygen. During processing, a plasma is formed from the process gas. In some implementations, the process gas provided includes at least one chlorine source and at least one oxygen source. Process gases may include (i) one or more chlorine-containing gases, (ii) one or more oxygen-containing gases, and (iii) optionally one or more inert carrier gases. In one implementation, the processing gas does not include fluorine.

The ratio of oxygen to chlorine gases can be controlled. The chlorine-containing and oxygen-containing gases can be combined to provide an atomic ratio of oxygen to chlorine. In some implementations, providing the oxygen source and the chlorine source includes providing an atomic ratio of oxygen to chlorine between about 40:60 and about 85:15. In some implementations, the atomic ratio of the oxygen to chlorine is between about 1:4 and about 2.3:1. For example, in some implementations, the volumetric flow ratio of the oxygen-containing source gas to the chlorine containing source gas is greater than 1 to 4 and less 4 to 1. In some implementations, volumetric flow ratio of the oxygen-containing ion source gas to the chlorine containing ion source gas is about 2.3 to 1. To illustrate, a 2.3 to 1 ratio volumetric flow ratio is obtained by using about 700 standard cubic centimeters (sccm) of diatomic oxygen (O₂) and about 300 sccm of diatomic chlorine (Cl₂). Gas flow rates may be controlled using a mass flow controller. MFCs can be controlled by a central controller 901. In some implementations, a Cl₂ gas source is provided at about 300 sccm and a O₂ gas source is provided at about 700 sccm. The individual and total gas flows of the processing gas may vary based on a number of processing factors, such as the size of the chamber, the size of the substrate being processed, and the specific etching profile desired, etc.

The process gas can be ionized in the remote plasma generator to generate plasma. A downstream plasma system configuration, for example, as shown in FIG. 9, may be used to form plasma remotely and channel the desired species to the chamber 910. The species provided from plasma source, also referred to as activated species, can either be charged (ions) or neutral (atoms and radicals).

Generally, radio frequency (RF) power levels within the range of about 2000 to 4000 watts can be used, with typical RF power levels of about 2000 watts. The power levels may vary based on a number of processing factors, such as the remote plasma generator used, the type and size of the chamber, etc.

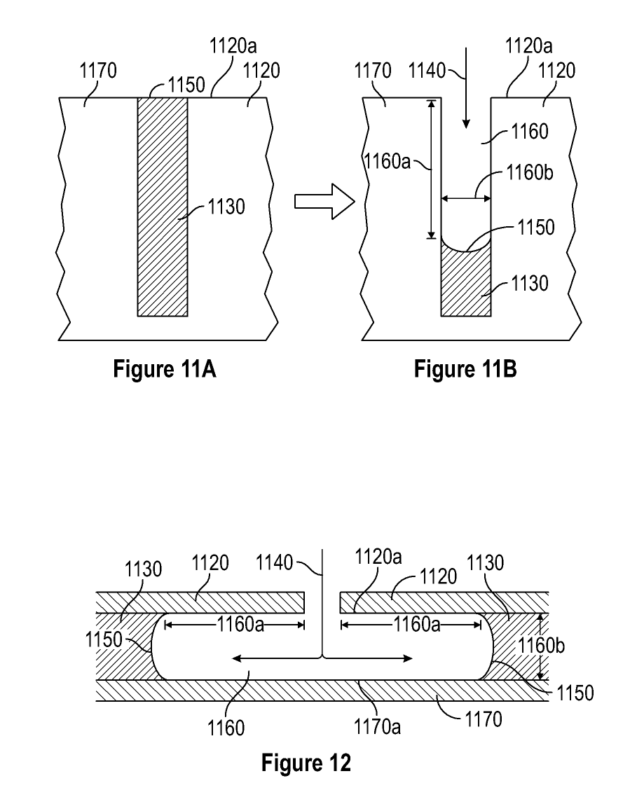

At block 1030 for selectively etching the electronic device, the activated species selectively etch molybdenum relative to the at least one structural material. In some implementations, the selective etching using remotely activated chlorine and oxygen can be employed in a “self-limiting” manner. For example, in some implementations, the etch is self-limiting because the etch front stops before all the sacrificial material, for example, molybdenum, is removed even if etchant continues to be supplied. In some implementations, the etch is self-limiting because the molybdenum is embedded in structural material such that a cavity is formed during the etching (for example, the cavity can be surrounded by structural material). In one implementation, the etch is self-limiting because the cavity so formed has one or more dimensions or widths that is less than 10 times the mean free path and an aspect ratio of depth to width greater than 10. Further discussion of “self-limited” etching as discussed herein, can be found for example with respect to FIGS. 11A-B below.

During the etch process, the plasma products generate volatile etch products from the chemical reactions between the elements of the material etched and the reactive species generated by the plasma. For example, in some implementations, a plasma generated from Cl₂ and O₂ may form MoOCl₄ or MoO₂Cl₂ when reacted with molybdenum. As will be discussed in more detail below, some volatile etch products formed from the chemical reactions with molybdenum, such as MoOCl₄ and MoO₂Cl₂, have much higher vapor pressure than others, such as MoCl₆, and can be volatile at 100° C. or higher. Therefore, in some implementations, Mo can be etched very fast with Cl₂/O₂ downstream plasma at high temperatures, e.g., greater than 100° C.

In some implementations, by using the etch methods disclosed herein, nearly 100% etch selectivity between molybdenum and certain structural materials can be obtained.

In some implementations, etching selectivity is expressed as a ratio between an etching rate of a target material and an etching rate of a structural material and/or a surface of the structural material. The etching rate for a particular material will differ depending on factors known in the art, for example, the identity of the etchant, etchant concentration, temperature, and the like. In the fabrication of EMS (e.g., NEMS or MEMS) devices, one factor affecting etch rate within cavities or other difficult-to-access regions is the effect of recombination, which deactivates and degrades the effectiveness of the etchant species. For example, as discussed above, etchant can access the sacrificial material 25 of unreleased IMODs (see FIG. 8D) through etch holes, from between strips of the movable reflective layer 14 and from the edges of the array. A person having ordinary skill in the art will understand that the recombination of the active species of the etchant in such devices depends in part on the mean free path, which depends on factors known in the art, for example, on the size of the etching hole(s), the dimensions of the cavity, the shape of the cavity, the temperature and pressure in the reaction chamber, and the like. In some implementations, the mean free path changes as the etch front proceeds, for example, to regions remote from the etch holes and/or edges of the device. Consequently, in some implementations, the etching rate of a target material in a constrained volume, for example, in forming a cavity, is different from the etching rate of the same material in an unconstrained volume, for example, on an outer surface of a device or in a bulk sample of the material. For example, as the etch front progresses and becomes buried farther from the etch holes in a constrained volume, active species are more likely to recombine (become inactive) through collisions. As discussed above, the observed etching rate of a target material, rate of recombination and lifespan of the active species depends at least in part on the shape, size, and dimensions of the constrained volume. Because these factors change over the course of an etching reaction, the etching rates also change as etching progresses.

In some implementations, etching rates are expressed as average etching rates over an entire etching process. In other implementations, etching rates are expressed as average etching rates over a portion of an etching process. In other implementations, etching rates are expressed as rates at one or more particular time points in an etching process. Unless otherwise specified, etching rates disclosed herein are average rates over an entire etching process. Etching rates are also expressible in units of mass per time (e.g., g/sec), amount per time (e.g., mol/sec), volume per time (e.g., mL/sec), and/or distance per time (e.g., μ/sec). Etching rates are typically expressed in distance per time herein, which depends upon the thickness of the target material as well as size and distribution of etch access openings, although those skilled in the art will understand that the rates can be expressed using different units.

Other factors which may affect the mean free path and thus the rate of recombination can include pressure and/or temperature. For example, at low pressure, the mean free path of reactive ions increases. This increases the reactive ion concentration at the etch layer, which in turn, increases active etch duration. In some implementations, the reaction chamber pressure over at least a portion of the etching process is from about 300 mTorr to about 1000 mTorr. In some implementations, the reaction chamber pressure over at least a portion of the etching process is from about 400 mTorr to about 700 mTorr. In some implementations, the reaction chamber pressure over at least a portion of the etching process is about 600 mTorr.

A person of ordinary skill in the art will understand that the rate of recombination and thus the etching rate can also vary with the temperature at which the etching process is performed. In some implementations, at least a portion of the etching process is performed at about 80° C. to about 300° C.; in some implementations from about 100° C. to about 250° C.; and in some implementations from about 150° C. to about 200° C. Temperatures can be maintained below those at which structural materials can be damaged.

In some implementations, the structural material that remains unetched by the selective etch includes at least one of aluminum (Al), aluminum oxide (Al₂O₃), an aluminum alloy, silicon dioxide (SiO₂), silicon oxynitride (SiOₓN_{y}), nickel (Ni), iron (Fe), platinum (Pt) and gold (Au).

In some implementations, three or more of the above structure materials are present and remain substantially undamaged by the selective etch. In some implementations, the structural materials include a surface that faces the cavity. Chlorine- and oxygen-containing remote plasma etch has been found to demonstrate extremely good selectivity to these materials. Unlike in situ plasmas, the remote plasma results in little energetic ion bombardment and therefore may not physically damage the structural materials.

Further, the oxygen containing gas in the processing gas may be used to inhibit, or limit by polymerization, the etching of the one or more structural materials. For example, in some implementations, the activated oxygen species may form a native oxide layer on the surface of the one or more structural materials. In some implementations, metal surface oxidation may be the dominant surface reaction on the structural material. For example, an oxygen: to chlorine atomic ratio of greater than about 1 to 4 can protect aluminum by forming aluminum oxide. In some implementations, formation of the native oxide layer can prevent forming AlCl₃ which is a volatile compound. For example, it will be appreciated from the disclosure herein that Al metal remains substantially undamaged by the selective etch if atomic oxygen content in the etch chemistry is about 20% or higher. Without being limited by theory, it is believed Al surface oxidation is the dominant surface reaction and thus prevents the formation of the volatile compound AlCl₃.

Byproducts of the oxygen containing gas, such as hydrogen in the case of H₂O as an oxygen source compound, do not substantially affect the structural materials.

In some implementations, a method of selectively etching molybdenum in a self-limiting manner is provided. The method includes providing a partially fabricated electronic device on a substrate in a reaction chamber. The partially fabricated electronic device includes molybdenum and at least one structural material. The method includes providing a chlorine source and an oxygen source through a remote plasma generator to form activated species of chlorine and oxygen. The method includes selectively etching the molybdenum relative to the at least one structural material by delivering the activated species of chlorine and oxygen from the remote plasma generator to the partially fabricated electronic device in the reaction chamber.

FIGS. 11A-12 show examples of cross sectional views illustrating aspects of a process flow for self-limiting etching of molybdenum. With reference to FIGS. 11A-B and FIG. 12, in some implementations, the selectively etching includes only partially removing molybdenum 1130 from within the at least one structural material 1120 and 1170. In some implementations, the at least one structural material is on at least two opposite sides of the molybdenum (e.g., structural materials 1120 and 1170, which can be the same materials). In some implementations, a cavity 1160 forms as an etch front 1150 progresses during selectively etching between the structural materials 1120 and 1170 on the at least two opposite sides the molybdenum 1130.

In some implementations, the selective etching is self-limiting. As discussed in more detail herein, the self-limiting manner of the etch can be defined in various ways. For example, in some implementations, the etch is self-limiting because the etch front stops before all the sacrificial material, for example, molybdenum, is removed even if etchant continues to be supplied. In some implementations, the etch is self-limiting because the molybdenum is embedded in structural material such that a cavity is formed during the etching. For example, the cavity so formed can be surrounded by structural material. In one implementation, the etch is self-limiting because the cavity so formed has one or more dimensions or widths that is less than 10 times the mean free path and an aspect ratio of depth to width greater than 10.

In some implementations, selective etching stops before all Mo is removed. Without being limited by theory, it is believed this happens because confined volumes of space cause more collisions of the active species with each other and the wall of the cavity being formed, which in turn cause more recombination of the active species. Recombination of the active species deactivates the etchant and slows or stops the etching reaction. In some implementations, the more confined the volume of space, the higher the recombination rate. The mean free path (λ) can be calculated for given etch conditions, for example, using the formula below:

$$λ = \frac{{k}_{B} T}{\sqrt{2 π } {d}^{2} ρ} \} \begin{matrix}{k}_{B} = Boltzman Constant \\ T = Temperature ( K ) \\ ρ = press ( Pa ) \\ d = diameter of gas particles ( m )\end{matrix}$$

In some implementations, for example in low vacuum (0.5-1 Torr), the mean free path is between about 50 and about 500 μm.

As discussed herein, depending in part on the dimensions of the structure, when etching between two structural materials, after a cavity of a particular depth is reached, the etching front proceeds no farther and some molybdenum remains unetched despite continued provision of etchants through the remote plasma generator.

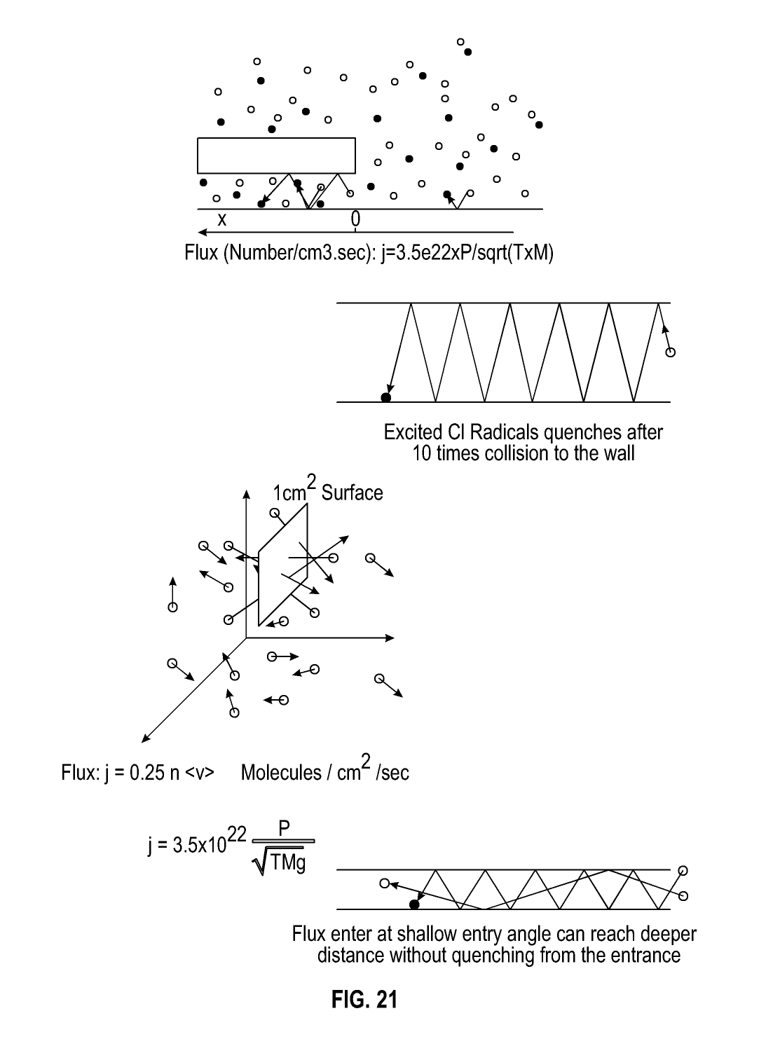

FIG. 21 illustrates examples of paths of activated species in cavities.

In some implementations, the mean free path is longer than a length of the cavity 19. For example, under a process condition of 0.5 Torr to 1 Torr the mean free path can be 50 μm (50,000 Å) or longer and the width or height of the cavity can be about 1000 Å to about 5000 Å. Under such conditions, where the mean free path is significantly (e.g., greater than times) larger than the width of the cavity, molecular flow conditions obtain in the cavity, and the active species extinguish and the etch front stops self-limitingly.

In some implementations, during the etch process, the activated species such as Cl*, Cl₂*, O*, O₃, etc react with Mo to form MoOₓCl_{y}. In some implementations, the MoOₓCl_{y} is volatile and can be removed from the cavity as gas species.

In some implementations, the activates species collide with the wall many times before reaching the etch front (for example, the Mo surface in the cavity). In some implementations, the activated species can become non-reactive species. For example, activated species can become non-reactive after a number of collisions with the cavity wall, or can adsorb on the wall, after reacting with molecules of the cavity wall, and/or after energy transfer to other molecules of the cavity wall. In some implementations, the non-reactive or adsorbed species cannot etch Mo. Therefore, the reaction speed of the etch can decrease as the etching depth becomes deeper (for example, as the etch front progresses). It will be appreciated from the disclosure herein, that some activated species have a short life span in the cavity, while other activated species have a longer life span in the cavity. For example, some activated species can become non-reactive after a small number of collisions with the wall of the cavity. In some implementations, activated species with a longer life span can reach a deeper depth in the cavity than activated species with a shorter life span. Activated species of chlorine can have a short life span in the cavity. In some implementations, activated species of chlorine become non-reactive after a small number of collisions with the wall of the cavity. Activated species of oxygen, for example, ozone (O₃) can have a longer life span in the cavity, compared to chlorine species, and can reach a deeper depth in the cavity. Without being limited by theory, it is believed that activated species of chlorine become deactivated faster than activated species of O₃ in the cavity. In some implementations, Mo oxidation becomes the dominant reaction at the etch front. For example, Mo+O₃→MoO₃. In some implementations, MoO₃ is very stable and cannot be etched by activated species of chlorine. Thus, in some implementations, etching Mo with downstream Cl₂/O₂ mixture can be self-limited.

It will be appreciated from the disclosure herein that the depth of the cavity can be controlled by the width of the cavity and the ratio of O₂/Cl₂ gas.

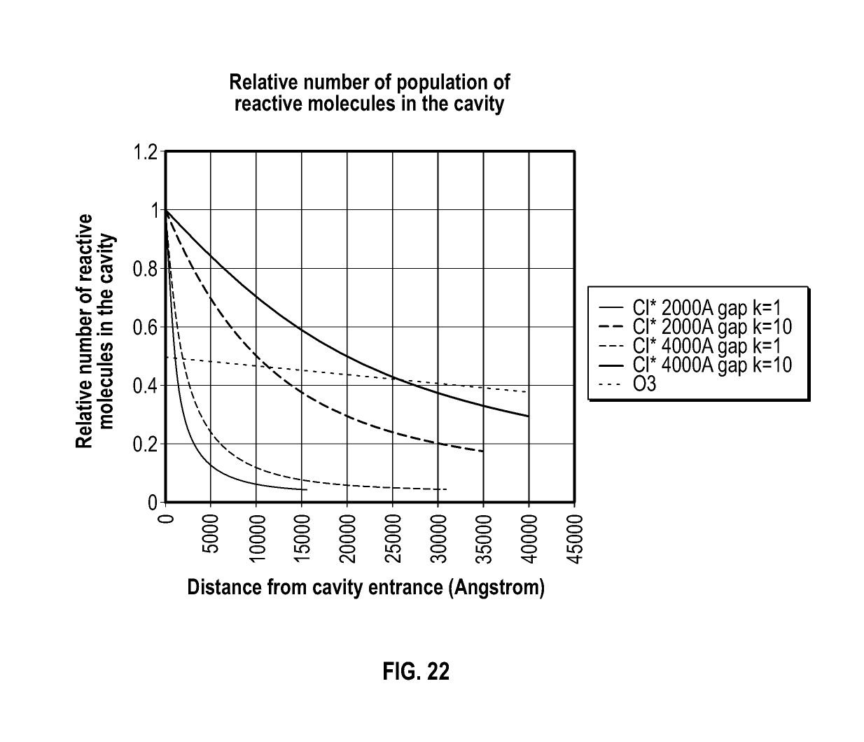

FIG. 22 is a graph illustrating examples of the relative number of active species of a gas versus the distance from the entrance of a cavity for different activated species of gas. In some implementations, the number of activated species can be governed by the following equation:

$$N = 1 - \frac{2}{π} ATAN [ \frac{k X}{0.5 D} ] \} \begin{matrix}N = Relative number of reactive species \\ in the cavity at X ( distance ) \\ k = number of collisions with cavity wall \\ to form non \text{-} reactive species \\ X = distance from cavity \\ D = cavity width\end{matrix}$$

The curves in FIG. 22 illustrate the relative number of activated species for k=10 and a cavity width of 2000 Å As illustrated in FIG. 22, in some implementations, oxidation becomes dominant if the relative number of O₃ species is approximately equal to the relative number of activated species of chlorine. In some implementations, the etch front stops at about 1 μm depth for a cavity width of about 2000 Å. In some implementations, the etch front stops at about 2.5 μm for a cavity width of about 4000 Å.

In some implementations, the etch only partially removes the molybdenum 1130, regardless of the duration of exposure to the etchants, leaving remaining molybdenum embedded within the structural materials 1120 and 1170.

In some implementations, the etch front 1150 on the remaining molybdenum after self-termination can have a reentrant shape.

As illustrated in FIGS. 11A-11B, in some implementations, the direction of the etch front 1150 progress is perpendicular to a major substrate surface (e.g., surface 1120a), and the width of the cavity 1160 is parallel to the major substrate surface. In some implementations, the cavity 1160 can be a hole in the structural material(s). In some implementations, the hole can be substantially cylindrical, substantially rectangular or form a channel. For example, in some implementations, a channel or gap between strips of the movable reflective layer across the array can be formed.

With reference to FIG. 12, in some implementations, the direction of the etch front 1150 progress is substantially parallel to a major substrate surface (e.g., surface 1120a or surface 1170a), and the width of the cavity 1160b is perpendicular to the major substrate surface (e.g., surface 1120a or surface 1170a). In the implementation of FIG. 12, a buried cavity 1160 is formed between structural material 1120 and 1170 as the sacrificial material 1130 is removed. In some implementations, the etch front 1150 can progress in more than one direction.

In some implementations, the molybdenum 1130 is selectively etched relative to at least one structural material 1120 and 1170. In some implementations, the at least one structural material 1120 and 1170 includes one or more of aluminum oxide (Al₂O₃), silicon dioxide (SiO₂), silicon oxynitride (SiON), nickel (Ni), iron (Fe), platinum (Pt) and gold (Au). In some implementations, the at least one structural material 1120 and 1170 includes aluminum (Al). In some implementations, the at least one structural material 1120 and 1170 includes at least one of silicon or silicon nitride. Unlike fluorine-based etchants, chlorine-based etching can selectively etch molybdenum without damaging silicon and silicon nitride structural materials.

As discussed above, in some implementations, the selectivity and/or etch rate can be adjusted as desired by controlling the oxygen to chlorine ratio.

In some implementations, activated oxygen species can form a native oxide layer with a metallic structural material, while the activated chlorine species etches the molybdenum. For example, aluminum can be etched by chlorine species, but under suitable conditions with oxygen in the etching species, the etching species can form a native oxide layer of about 15 to about 40 Angstroms in thickness. In some IMOD implementations, where the reflector exposed to the substrate includes aluminum, the protective native oxide layer does not affect optics. For example, in some implementations, the native oxide layer formed can be sufficiently thin so as not to affect the optical path length in such a way to substantially change the interference colors.

The etch methods disclosed herein, can be used to fabricate electromechanical systems (EMS) devices on a substrate, as discussed below and the partially fabricated electronic device is a partially fabricated electromechanical systems (EMS) device, such as a microelectromechanical systems (MEMS) device. In some implementations, the EMS device is an optical EMS device, such as an interferometric modulator (IMOD).

FIGS. 13A-13D show examples of cross sectional views during various stages of self-limiting etching of sacrificial material during the fabrication of an electromechanical systems device. Like numbers are used to reference similar parts to those of FIGS. 6A-6E. Support structures can be formed from a release etch that forms the MEMS cavity. In this instance, the support structures can be formed from the same sacrificial molybdenum material that fills the cavity prior to the release etch.

Removal techniques are applied to remove the molybdenum, leaving remaining portions of the molybdenum behind to form at least part of the support structures. The removal techniques are selective between the molybdenum and other surrounding materials but chemically non-selective between the sacrificial and remaining portions of the molybdenum.

For example, FIG. 13A illustrates a cross section of an unreleased interferometric modulator array including a substrate 20, a black mask structure 23, a spacer layer 35, an optical stack 16, a sacrificial layer 25, and a movable reflective layer 14 similar to the interferometric modulator illustrated in FIG. 6D. A person having ordinary skill in the art will understand that similar considerations also apply to the release etch of MEMS devices of other designs. In the illustrated implementation, the movable reflective layer 14 is deformable and may function as a movable electrode in the resulting interferometric modulator, and thus may be referred to as a mechanical layer, deformable layer, or movable electrode herein. Support structures 18 can be formed as described below. As noted above, such support structures 18 can include continuous wall, rails, and/or isolated posts.

The structure 1300 may be fabricated by sequential deposition and patterning of the illustrated layers. The sacrificial layer 25 is a material that is capable of being selectively etched relative to other surrounding materials (e.g., the movable reflective layer 14 and optical stack 16) by exposure to a suitable etchant to remove a sacrificial portion. The material making up the sacrificial layer 25 is molybdenum and the etchant includes activated chlorine/oxygen species in the illustrated implementation.

FIG. 13B illustrates the formation of vias 1305 through the movable reflective layer 14 to expose the sacrificial layer 25. The vias 1305 are formed in the movable reflective layer 14 over areas of structure 1300 where in which the creation of optical cavities is desired, as explained in greater detail below. The vias 1305 may be formed by masking and etching techniques known to those skilled in the art. Openings through which the etchant can access the sacrificial layer 25 can also include exposed edges at the periphery of the array and gaps between strips of the movable reflective layer across the array.

FIG. 13C illustrates the initial etching of the sacrificial layer 25 though the vias 1305, forming cavities. In the illustrated implementation, the etchant accesses the sacrificial layer 25 through the etching vias 1305 and other openings. At this stage, portions of the support layer 14b (e.g., silicon oxide, silicon nitride, silicon or silicon oxynitride) and the reflective sub-layer 14c (e.g., aluminum copper alloy) are exposed to the etchant. The process continues as illustrated in FIG. 13D to isotropically selectively etch the sacrificial layer 25 without substantially etching the movable reflective layer 14 or optical stack 16. Suitable selective etchants may be selected as discussed above. In the illustrated implementation, etching of the sacrificial layer 25 by the etchant 1310 proceeds by forming cavities that laterally undercut the movable reflective layer 14 and expand in size to form cavities 19 over the course of the etching process. The cavities 19 allow movement of the movable reflective layer 14 and will serve as optical cavities for the illustrated IMOD implementation. The vias 1305 are positioned and the etching conditions are selected so that the etchant 1310 removes a sacrificial portion of the sacrificial layer 25 under the movable reflective layer 14 to form the optical cavities 19 over a first area of the optical stack 16, and so that the remaining portion of the sacrificial layer 25 forms support structures 18 that provide support to the movable reflective layer 14 over a second area of optical stack 16. In the illustrated implementation, the support structures 18 overlap with the black mask structure 23 to provide a black appearance in this optically inactive region. Fabrication may continue to finish making an EMS device such as an interferometric modulator. In the illustrated implementation, the post structures 18 have a re-entrant profile that is generally concave in cross-section.

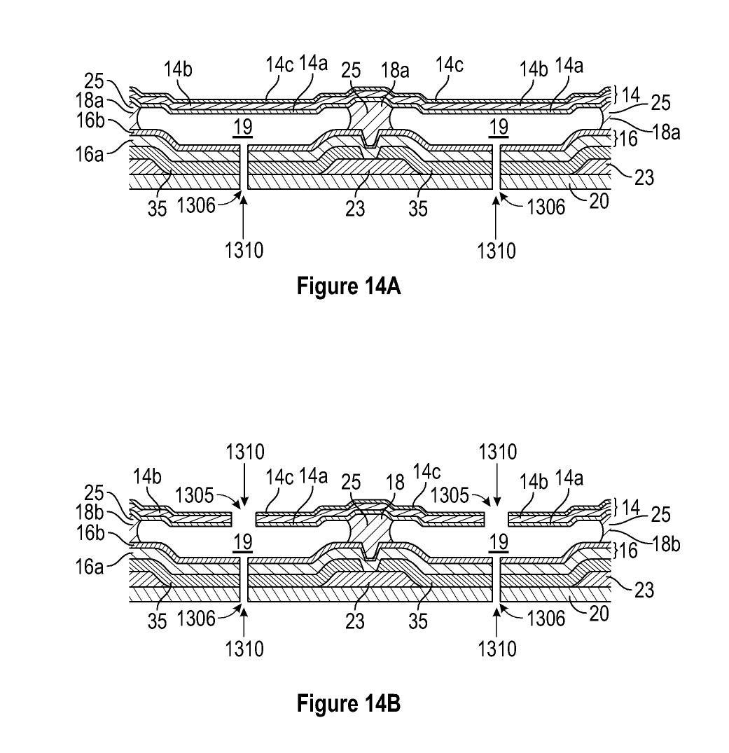

FIGS. 14A and 14B illustrate the results of self-limited removal of sacrificial material with different etch hole locations. FIG. 14A illustrates another implementation in which the etchant 1310 enters through apertures 1306 formed through the substrate 20. In still another implementation illustrated in FIG. 14B, the etchant 1310 enters through both the vias 1305 and the apertures 1306.

The positioning of the vias 1305, apertures 1306 and other etch access openings, and the selection of the etching conditions to produce cavities and post structures as illustrated in FIGS. 13A-14B, may be accomplished in various ways.

As discussed above, some implementations of unreleased interferometric modulators permit etchant access through, for example, one or more of the sides of the device. In some implementations, the movable electrode layer is part of a plurality of movable electrode strips and selectively etching includes providing the activated species of chlorine and oxygen through openings between the strips. In some implementations, the movable electrode includes a reflective layer having a reflective surface.

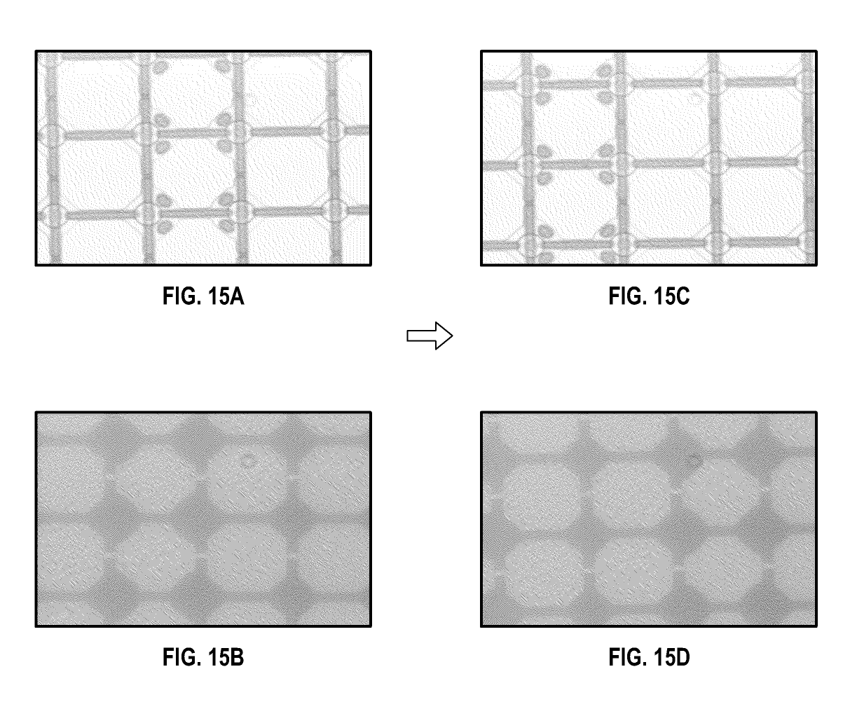

FIGS. 15A-15D show example top view photomicrographs depicting the progressive molybdenum etching by chlorine/oxygen active species etchant introduced through etch openings. As shown in FIG. 15A-15D, an array of cavities results from etching sacrificial molybdenum material of a partially fabricated EMS device, resulting from the introduction of a Cl₂/O₂ etchant source gas through a corresponding distribution of etch openings. Cl₂/O₂ activated etchant was introduced through the vias to etch a molybdenum material. The photomicrograph shows that the Cl₂/O₂ activated etchant flows through the via and then etches the molybdenum in a generally radial pattern to form a cavity. This flow pattern may be utilized to produce an array of interferometric modulator cavities and post structures as illustrated by the series of photomicrographs shown in FIGS. 15A-15D.

The photomicrographs shown in FIGS. 15A-15B were taken after a Cl₂ (500 sccm) and O₂ (500 sccm) activated etchant was introduced through the etch holes for about 1800 seconds by the end of which Mo etching stopped self-limitingly. FIGS. 15C-15D show photomicrographs of the interferometric modulator substrates exposed to a second Cl₂ (300 sccm) and O₂ (700 sccm) activated etchant, which was introduced through the vias for about 1800 seconds (μm). The etch holes had dimensions of about 5 microns and the chamber conditions were in the range of about 600 mTorr and 150° C. during the etching processes illustrated in FIGS. 15A-D. In some implementations, as the self-limiting etching terminates, the cavity edges merge prior to complete removal of the molybdenum material, and remaining material is left behind to form support structures. For example, the post 1510 in FIGS. 15B and 15D may be formed by introducing Cl₂/O₂ etchant through the vias until the corresponding cavities merge.

In some implementations, support structures may be formed by introducing a Cl₂/O₂ etchant through a series of horizontal and vertical etch holes or openings. The vertical etch holes are openings or channels in the overlying or covering layer(s), exposing the underlying molybdenum material.

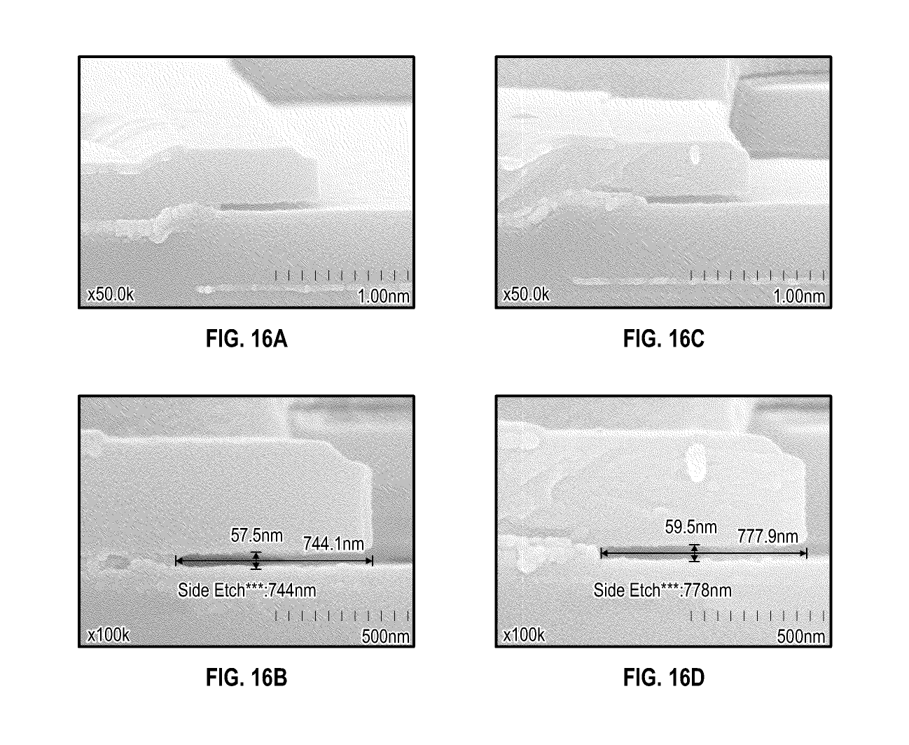

FIGS. 16A-16D show example cross sectional photomicrographs of the examples of FIGS. 15A-15D. As illustrated in FIGS. 16A-16B, the depth of the etch is about 744 nm and the width of the cavity is about 57 nm. As illustrated in FIGS. 16C-16D, following the second selective etch, the depth of the etch is about 778 nm and the width of the cavity is about 59 nm.

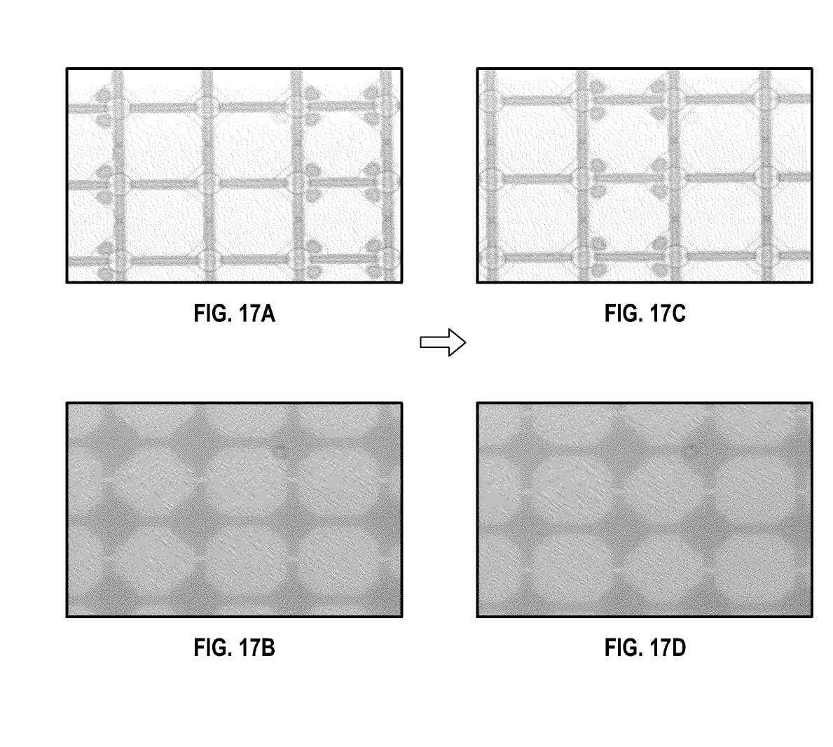

FIGS. 17A-17D show example top view photomicrographs depicting the progressive molybdenum etching by chlorine/oxygen active species etchant flowing through etch holes.

The photomicrograph shown in FIGS. 17A-B were taken after a Cl₂ (500 sccm) and O₂ (500 sccm) etchant was introduced through the etch holes for about 1800 seconds. FIGS. 15C-15D show photomicrographs of the interferometric modulator substrates exposed to a second Cl₂ (300 sccm) and O₂ (700 sccm) remote plasma activator etchant, which was introduced through the vias for about 1800 seconds. The chamber conditions were in the range of about 600 mTorr and 200° C. during the etching processes illustrated in FIGS. 17A-17D.

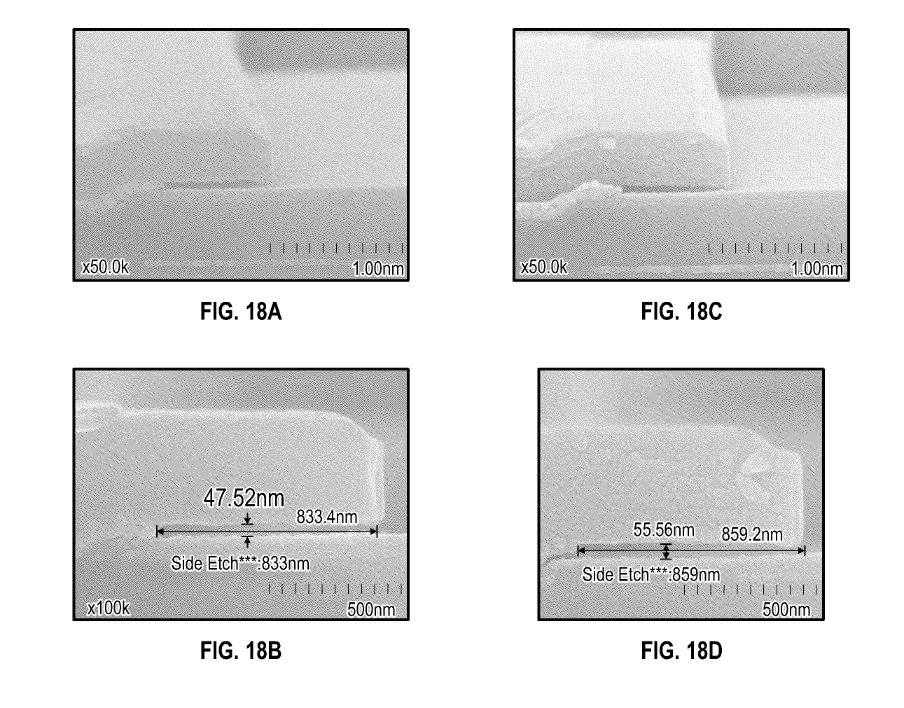

FIGS. 18A-18D show example cross-sectional photomicrographs of the examples of FIGS. 17A-17D. As illustrated in the photomicrographs of FIGS. 18A-B, the depth of the etch is about 833 nm and the width of the cavity is about 47 nm. As illustrated in the photomicrographs of FIGS. 18C-18D1C-16D, following the second selective etch, the depth of the etch is about 859 nm and the width of the etch is about 55 nm.

As illustrated in the progression from FIGS. 18A-B (corresponding to FIG. 17B) to FIGS. 18C-D (corresponding to FIG. 17D), the second etchant did not substantially increase the etch depth. Thus, the etch front progression terminated despite further exposure to the etchant. It will be appreciated from the disclosure herein that the selective etching process is self-limiting.

Persons having ordinary skill in the art will understand that etch access openings can be distributed and configured to facilitate both etching of the material layer to form the cavity and shaping of the support structure, and operation of the resulting EMS device. Thus, for example, apertures in the movable electrode layer of an EMS device can be configured to reduce negative impact on the functioning of the movable electrode layer. Routine experimentation may be used to identify optimum aperture configurations, distributions and etching conditions.

The etching rate may be adjusted as desired by controlling the chamber pressure, controlling the chamber temperature and/or introducing the chlorine/oxygen gas to the chamber in admixture with other carrier gas(es).

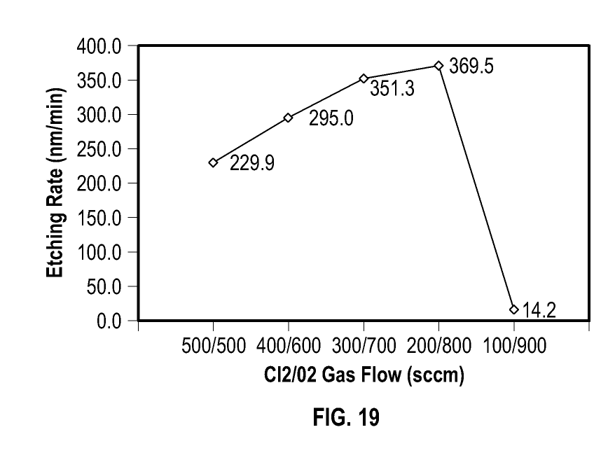

FIG. 19 shows an example graph of the etching rate dependence on gas flow ratio provided through a remote plasma generator. In some implementations, the etching rate may increase as the ratio of O₂ to Cl₂ increases. For example, in some implementations, a gas flow ratio of 600 sccm O₂ to 400 sccm Cl₂ can result in an etch rate of about 295 nm/minute, whereas a gas flow ratio of 800 sccm O₂ to 200 sccm Cl₂ can result in an etch rate of about 369 nm/minute. In some implementations, a gas flow ratio with high O₂ can result in a decreased etch rate. For example, in some implementations, a gas flow ratio of 900 sccm O₂ to 100 sccm Cl₂ can result in an etch rate of about 14 nm/minute.

An inert or carrier gas can be added to the process gas. For example, in some implementations, the carrier gas can include at least one of nitrogen (N₂), argon (Ar), neon (Ne), xenon (Xe) and krypton (Kr). It will be appreciated from the disclosure herein that introducing other carrier gases can dilute the plasma and slow down the etching process. The carrier gas may decrease the reactive ion concentration at the etch front and hence decrease the etch rate.

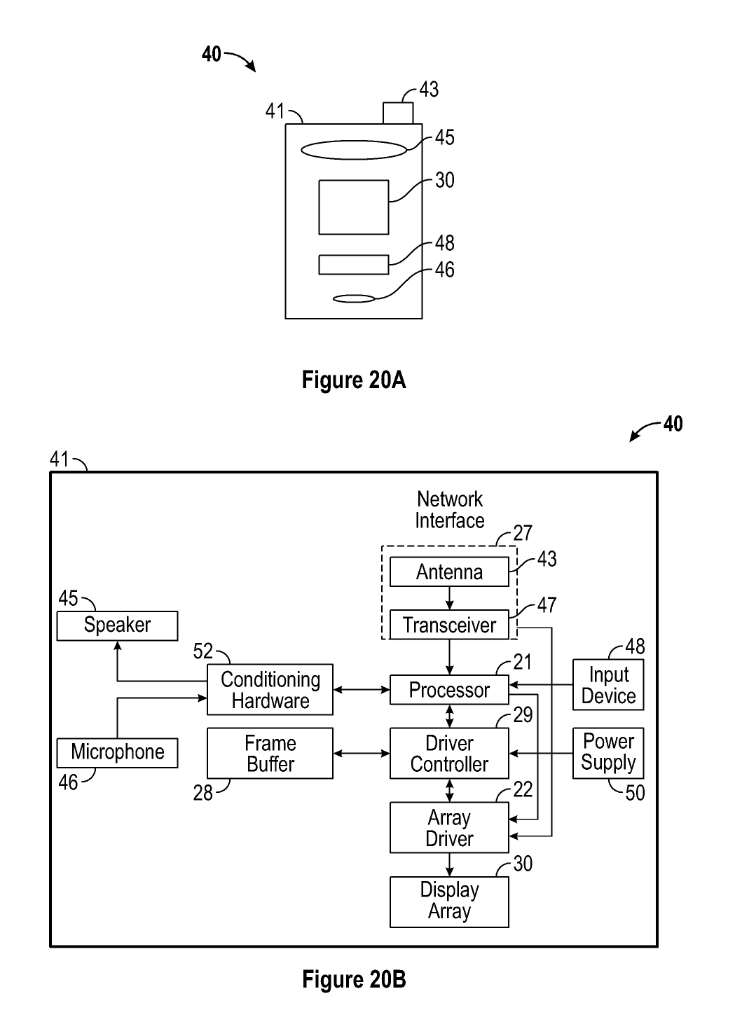

FIGS. 20A and 20B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of selectively etching molybdenum, comprising:
providing a partially fabricated electronic device on a substrate in a reaction chamber, wherein the partially fabricated electronic device includes molybdenum and at least one structural material;
providing a chlorine source and an oxygen source through a remote plasma generator to form activated species of chlorine and oxygen; and
selectively etching the molybdenum relative to the at least one structural material by delivering the activated species of chlorine and oxygen from the remote plasma generator to the partially fabricated electronic device in the reaction chamber, wherein selectively etching is self-limiting.

2. The method of claim 1, wherein selectively etching includes only partially removing the molybdenum from within the at least one structural material of the partially fabricated electronic device, the molybdenum being embedded in the at least one structural material.

3. The method of claim 2, wherein the partially fabricated electronic device is a partially fabricated electromechanical systems (EMS) device, and selectively etching includes removing the molybdenum from between electrodes of the partially fabricated EMS device.

4. The method of claim 3, wherein the electrodes include a first electrode layer having a reflective surface and a stationary electrode layer having a partially reflective metallic or semiconducting absorber, the first electrode layer becomes movable after the molybdenum is removed.

5. The method of claim 4, wherein the first electrode layer is part of a plurality of electrode strips and selectively etching includes providing the activated species of chlorine and oxygen through openings between the strips.

6. The method of claim 4, wherein selectively etching further includes providing the activated species of chlorine and oxygen through at least one etch hole through the first electrode layer.

7. The method of claim 4, wherein the reflective surface includes aluminum (Al).

8. The method of claim 4, wherein the first electrode layer includes a dielectric support layer between a first metallic layer and a second metallic layer, wherein the first metallic layer and the second metallic layer include aluminum and copper.

9. The method of claim 2, wherein an etch front during selectively etching progresses between structural material on at least two opposite sides of the molybdenum to form a cavity until a depth of the cavity in a direction of the etch front progress is at least 10 times a width of the cavity in a direction perpendicular to the direction of etch progress.

10. The method of claim 9, wherein the selective etch self-limitingly stops while the depth of the cavity is less than 25 times the width of the cavity.

11. The method of claim 9, wherein the direction of the etch front progress is parallel to a major substrate surface, and the width of the cavity is perpendicular to the major substrate surface.

12. The method of claim 9, wherein the direction of the etch front progress is perpendicular to a major substrate surface, and the width of the cavity is parallel to the major substrate surface.

13. The method of claim 1, wherein the at least one structural material includes aluminum (Al).

14. The method of claim 13, wherein the at least one structural material further includes one or more of aluminum oxide (Al₂O₃), silicon dioxide (SiO₂), silicon oxynitride (SiON), nickel (Ni), iron (Fe), platinum (Pt) and gold (Au).

15. The method of claim 1, wherein the at least one structural material includes at least one of silicon or silicon nitride.

16. The method of claim 1, wherein selectively etching includes maintaining the substrate at a temperature ranging between about 150° C. and about 250° C.

17. The method of claim 1, wherein providing the oxygen source and the chlorine source includes providing an atomic ratio of oxygen:chlorine between about 40:60 and about 85:15.

18. An electromechanical systems device comprising:
a substrate having a first electrode layer formed thereon;
a movable second electrode layer formed over the first electrode layer and spaced apart from the first electrode layer by a collapsible cavity;
at least one support structure supporting the movable second electrode layer over the first electrode layer, wherein the at least one support structure includes molybdenum,
wherein structural materials surrounding the collapsible cavity include at least one of silicon or silicon nitride.

19. The electromechanical systems device of claim 18, wherein the structural materials surrounding the collapsible cavity further include one or more of aluminum oxide (Al₂O₃), silicon dioxide (SiO₂), silicon oxynitride (SiON), nickel (Ni), iron (Fe), platinum (Pt) and gold (Au).

20. The electromechanical systems device of claim 18, where the structural materials surrounding the collapsible cavity further includes aluminum and aluminum oxide.

21. The electromechanical systems device of claim 18, wherein the at least one support structure has a re-entrant profile.

22. The electromechanical systems device of claim 18, wherein a length of the cavity parallel to the substrate is at least 50 times of a height of the cavity perpendicular to the substrate.

23. The electromechanical systems device of claim 18, wherein the electromechanical systems device is an interferometric modulator device.

24. A display apparatus, comprising:
the electromechanical systems device of claim 23;
a display;
a processor that is configured to communicate with the display, the processor being configured to process image data; and
a memory device that is configured to communicate with the processor.

25. The display apparatus of claim 24, further including:
a driver circuit configured to send at least one signal to the display.

26. The display apparatus of claim 25, further including:
a controller configured to send at least a portion of the image data to the driver circuit.

27. The display apparatus of claim 24, further including:
an image source module configured to send the image data to the processor.

28. An electromechanical systems device comprising:
a substrate having a first electrode layer formed thereon;
a movable second electrode layer formed over the first electrode layer and spaced apart from the first electrode layer by a cavity; and
a means for supporting the second electrode layer over the cavity including molybdenum,
wherein the electromechanical systems device includes at least one of silicon or silicon nitride exposed to the cavity.

29. The electromechanical systems device of claim 28, wherein the means for supporting is a support post.

30. The electromechanical systems device of claim 25, wherein the support post has a re-entrant profile.

31. The electromechanical systems device of claim 28, wherein the structural materials surrounding the collapsible cavity further include one or more of aluminum oxide (Al2O3), silicon dioxide (SiO₂), silicon oxynitride (SiON), nickel (Ni), iron (Fe), platinum (Pt) and gold (Au).

32. The electromechanical systems device of claim 28, where the structural materials surrounding the collapsible cavity further includes aluminum and aluminum oxide.
